(19) United States
(12) Patent Application Publication
(10) Pub. No.: US 2024/0371657 A1
(43) Pub. Date: Nov. 7, 2024

(54) MOUNTING DEVICE AND MOUNTING METHOD

(71) Applicant: TORAY ENGINEERING CO., LTD., Tokyo (JP)

(72) Inventors: Shimpei AOKI, Otsu-shi (JP); Takashi HARE, Otsu-shi (JP); Kenji HAMAKAWA, Otsu-shi (JP); Katsumi TERADA, Otsu-shi (JP)

(21) Appl. No.: 18/775,597

(22) Filed: Jul. 17, 2024

Related U.S. Application Data
(63) Continuation of application No. PCT/JP2022/047263, filed on Dec. 22, 2022.

(30) Foreign Application Priority Data
Jan. 21, 2022 (JP) 2022-007513

(51) Int. Cl. H01L 21/52; H01L 21/66; H01L 23/544

(52) U.S. Cl. CPC H01L 21/52; H01L 22/22; H01L 23/544; H01L 2223/54426

(57) ABSTRACT

A mounting device mounts a chip component having a chip recognition mark and a substrate having a substrate recognition mark. An attachment tool has transparency and has a tool recognition mark. The attachment tool holds a surface of the chip component opposite to a surface having the chip recognition mark. A chip position recognition unit simultaneously acquires position information of the chip recognition mark and of the tool recognition mark. The substrate position recognition unit acquires position information of the substrate recognition mark and of the tool recognition mark. A control unit moves a substrate stage holding the substrate or the attachment tool in the in-plane direction of the substrate on the basis of information obtained by the chip position recognition unit and by the substrate position recognition unit to perform alignment between the chip component and the substrate.

### CROSS-REFERENCE TO RELATED APPLICATIONS

This application is a continuation application of PCT International Application No. PCT/JP2022/047263 filed on Dec. 22, 2022, which claims priority to Japanese Patent Application No. 2022-007513 filed on Jan. 21, 2022 with Japan Patent Office. The entire disclosures of PCT International Application No. PCT/JP2022/047263 and Japanese Patent Application No. 2022-007513 are hereby incorporated herein by reference.

### BACKGROUND

### Field of the Invention

The present invention relates to a mounting device and a mounting method for mounting a chip component on a substrate. In particular, the present invention relates to a mounting device and a mounting method in which the electrode surface of the chip component is mounted facing the electrode surface of the substrate.

### Background Information

One form for mounting a semiconductor chip or other such chip component on a wiring substrate or other such substrate is face-down mounting, in which the electrode surface of the chip component is mounted facing the electrode surface of the substrate.

### SUMMARY

FIG. 17 shows an example of a substrate S for performing face-down mounting, in which chip components are bonded to mounting locations SC on the substrate S, with the electrode surfaces facing each other. At this time, unless the chip components are accurately placed in the mounting locations SC of the substrate S, the electrical connection between the substrate S and the chip components will be incomplete, resulting in poor quality of the semiconductor device. Therefore, a first substrate recognition mark AS1 and a second substrate recognition mark AS2 are provided as substrate recognition marks AS on the electrode surface side of each mounting location SC of the substrate S, as shown in FIG. 17. On the other hand, a first chip recognition mark AC1 and a second chip recognition mark AC2 are provided as chip recognition marks AC on the chip component C, and, in the state shown in FIG. 18, the relative position of the chip component C (in the in-plane direction of the substrate S) with respect to the mounting location SC of the substrate S is determined from the positional relationship between the first substrate recognition mark AS1 and the first chip recognition mark AC1 as well as the positional relationship between the second substrate recognition mark AS2 and the second chip recognition mark AC2, which can be corrected to improve positional accuracy.

Specifically, in the mounting device shown in FIG. 19, an upper and lower two-field camera 500 is used to perform imaging, with the first chip recognition mark AC1 (or the second chip recognition mark AC2) placed in the field of view of an upper field 50U of the upper and lower two-field camera 500, and the first substrate recognition mark AS1 (or the second substrate recognition mark AS2) placed in the field of view of the lower field 50D (FIG. 20).

By using this upper and lower two-field camera to calculate and correct the relative position of the chip component C (in the in-plane direction of the substrate S) with respect to the mounting location SC of the substrate S, it becomes possible to perform mounting with a maximum error of several μm.

In face-down mounting, or so-called flip chip mounting, a maximum error of several μm is sufficient when the electrode pitch is 100 μm, such as when solder bumps are used as the electrodes of the chip component C, but there is no allowance when the electrode pitch is just over 50 μm, such as when Cu pillar bumps are used, and, as mounting density increases and the electrode pitch becomes smaller, there are now applications for which the accuracy is insufficient.

Therefore, an upper and lower two-field camera is used to further improve accuracy, but in the state shown in FIG. 20, even if the chip component C is aligned with an error of less than 1 μm (in the in-plane direction of the substrate S) with respect to the mounting location SC of the substrate S, the maximum error at the mounting stage may exceed 1 μm. This is because, inter alia, when the chip C is lowered from the state shown in FIG. 20 toward the substrate S, there is a slight tilt in the direction of descent. For this reason, resolution is being attempted by increasing the machining accuracy and rigidity of each component of the mounting device such that the direction of descent becomes perpendicular to the surface that holds the substrate S, but this has an impact on the cost of the device.

It can be expected that mounting accuracy would be improved if alignment is performed in a state in which the substrate S and the chip component C are brought as close to each other as possible, but when an upper and lower two-field camera is used, it is difficult to significantly improve the current situation due to the focal length and the thickness of the camera itself.

On the other hand, in face-up mounting in which the electrode surface of the substrate S and the electrode surface of the chip component C face in the same direction, such as shown in FIG. 21, a mounting device 100 configured as shown in FIG. 22 can be used to observe, from the same direction, the positional relationship between the first substrate recognition mark AS1 and the first chip recognition mark AC1, as shown in FIG. 23A, as well as the positional relationship between the second substrate recognition mark AS2 and the second chip recognition mark AC2, as shown in FIG. 23B, so that it is possible to perform alignment in a state in which the substrate S and the chip component C are brought as close as possible to each other (see Japanese Laid-Open Patent Application Publication No. 2020-11970 (Patent Document 1), for example).

Therefore, it is possible in face-down mounting to provide chip recognition marks AC on the opposite side of the electrode surface of the chip component C to perform alignment in a state in which the substrate S and the chip component C are brought as close as possible to each other, in the same manner as in the face-up mounting shown in FIGS. 23A and 23B.

However, since the purpose of alignment is to achieve reliable bonding between the electrodes of the chip component C and the substrate S, the chip recognition marks AC must be provided on the electrodes of the chip component C with high precision, but placing chip recognition marks AC with high precision and accuracy relative to the electrodes on the opposite side is extremely difficult, making it unsuitable as a means of performing face-down mounting with high precision. It is also necessary to provide a new step for drawing the recognition marks on the opposite side of the electrode surface, which is not preferable in terms of process cost.

One object of the present disclosure is to provide a mounting device and a mounting method with which high-precision mounting with mounting accuracy of less than or equal to 1 μm can be achieved in face-down mounting, in which the electrode surfaces are mounted facing each other.

In order to solve the problem described above, according to a first aspect, a mounting device is configured to mount a chip component having a chip recognition mark for alignment and a substrate having a substrate recognition mark for alignment such that a surface having the chip recognition mark faces a surface having the substrate recognition mark. The mounting device comprises an attachment tool, a mounting head, an elevating unit, a substrate stage, a chip position recognition unit, a substrate position recognition unit and a control unit. The attachment tool has transparency and has a tool recognition mark. The attachment tool being configured to hold a surface of the chip component opposite to the surface having the chip recognition mark. The mounting head holds the attachment tool at a tip thereof. The elevating unit is configured to raise and lower the mounting head in a direction perpendicular to the substrate. The substrate stage is configured to hold the substrate. The chip position recognition unit is configured to simultaneously acquire position information of the chip recognition mark and position information of the tool recognition mark, in a state in which the chip component is held by the attachment tool. The substrate position recognition unit is configured to acquire position information of the substrate recognition mark and the position information of the tool recognition mark. The control unit is connected to the mounting head, the elevating unit, the substrate stage, the chip position recognition unit, and the substrate position recognition unit. At least one of the substrate stage and the attachment tool is movable in an in-plane direction of the substrate. The control unit is configured to move the substrate stage or the attachment tool in the in-plane direction of the substrate on the basis of information obtained by the chip position recognition unit and information obtained by the substrate position recognition unit to perform alignment between the chip component and the substrate.

According to a second aspect, with the mounting device according to the first aspect, the substrate position recognition unit is movable independent of the mounting head. The position information of at least one of the substrate recognition mark and of the tool recognition mark is acquired through the attachment tool.

According to a third aspect, with the mounting device according to the first or the second aspect, the mounting head has a tool position control unit that is configured to adjust a position of the attachment tool in an in-plane direction of the chip component.

According to a fourth aspect, the mounting device according to any one of the first to the third aspects further comprises a chip conveyance unit configured to convey the chip component to directly below the attachment tool. The chip conveyance unit includes a chip slider on which the chip component is placed and a conveyance rail that is configured to convey the chip slider. According to a fifth aspect, with the mounting device according to the fourth aspect, the chip conveyance unit includes a position adjustment unit that is configured to adjust an in-plane-direction position of the chip component placed on the chip slider.

According to a sixth aspect, with the mounting device according to any one of the first to the fifth aspects, the substrate position recognition unit is configured to simultaneously acquire the position information of the tool recognition mark and the position information of the substrate recognition mark, in a state in which the chip component is held by the attachment tool and is facing the substrate.

According to a seventh aspect, with the mounting device according to any one of the first to the fifth aspects, the substrate position recognition unit is configured to acquire the position information of the substrate recognition mark, in a state in which the chip component is not being held.

According to an eighth aspect, with the mounting device according to the seventh aspect, the attachment tool is brought close such that a distance between a lower surface of the attachment tool and an upper surface of the substrate becomes essentially equal to a thickness of the chip component, to simultaneously acquire the position information of the tool recognition mark and the position information of the substrate recognition mark.

According to a ninth aspect, a mounting method is provided for mounting a chip component having a chip recognition mark for alignment and a substrate having a substrate recognition mark for alignment such that a surface having the chip recognition mark facing a surface having the substrate recognition mark, using the mounting device according to any one of the first to fifth aspects. The mounting method comprises holding the substrate on the substrate stage, holding the chip component with the attachment tool having the tool recognition mark, acquiring the position information of the chip recognition mark and the position information of the tool recognition mark, in a state in which the chip component is held by the attachment tool, acquiring the position information of the tool recognition mark and the position information of the substrate recognition mark, in a state in which the chip component is held by the attachment tool and is facing the substrate, and adjusting the position of the chip component in the in-plane direction of the substrate, on the basis of information on relative positions of the substrate recognition mark and the chip recognition mark with respect to the tool recognition mark.

According to a tenth aspect, a mounting method is provided for mounting a chip component having a chip recognition mark for alignment and a substrate having a substrate recognition mark for alignment such that a surface having the chip recognition mark faces a surface having the substrate recognition mark, using the mounting device according to any one of the first to fifth aspects. The mounting method comprises holding the substrate on the substrate stage, acquiring the position information of the substrate recognition mark, holding the chip component with the attachment tool, acquiring the position information of the chip recognition mark and the position information of the tool recognition mark, in a state in which the chip component is held by the attachment tool, and adjusting the position of the chip component in the in-plane direction of the substrate, on the basis of information on the relative positions of the tool recognition mark and the chip recognition mark.

According to an eleventh aspect, with the mounting method according to the tenth aspect, in the acquiring of the position information of the substrate recognition mark, a distance between a lower surface of the attachment tool and an upper surface of the substrate is set to be essentially equal to a thickness of the chip component, to acquire the position information of the substrate recognition mark and the position information of the tool recognition mark.

By means of the present disclosure, it is possible to perform alignment in a state in which the electrode surfaces of the chip component and the substrate face each other and are close to each other, thereby making it possible to perform face-down mounting with high precision.

### BRIEF DESCRIPTION OF THE DRAWINGS

FIG. 1 is a schematic diagram of a mounting device according to an embodiment of the present disclosure.

FIGS. 2A and 2B are diagrams explaining an optical configuration according to the embodiment of the present disclosure, with FIG. 2A showing a front view of the optical configuration, and FIG. 2B showing a side view of the optical configuration.

FIG. 3 is a block diagram showing a control system according to the embodiment of the present disclosure.

FIGS. 4A and 4B are diagrams showing a chip position recognition means of the mounting device according to the embodiment of the present disclosure, with FIG. 4A showing a status of the chip position recognition means acquiring position information of a first chip recognition mark and position information of a first tool recognition mark, and FIG. 5B showing a status of the chip position recognition means acquiring position information of a second chip recognition mark and position information of a second tool recognition mark.

FIGS. 5A and 5B are diagrams showing sample images acquired by the chip position recognition means of the mounting device according to the embodiment of the present disclosure, with FIG. 5A showing a sample image of the first chip recognition mark and the first tool recognition mark, and FIG. 5B showing a sample image of the second chip recognition mark and the second tool recognition mark.

FIGS. 6A and 6B are diagrams showing a substrate position recognition means of the mounting device according to the embodiment of the present disclosure, with FIG. 6A showing a status of the substrate position recognition means acquiring position information of a first substrate recognition mark and position information of the first tool recognition mark, and FIG. 6B showing a status of the substrate position recognition means acquiring position information of a second substrate recognition mark and position information of the second tool recognition mark.

FIGS. 7A and 7B are diagrams showing sample images acquired by the substrate position recognition means of the mounting device according to the embodiment of the present disclosure, with FIG. 7A showing a sample image of the first substrate recognition mark and the first tool recognition mark, and FIG. 7B showing a sample image of the second substrate recognition mark and the second tool recognition mark.

FIG. 8 is a schematic diagram of a first modified example of the mounting device according to the embodiment of the present disclosure.

FIG. 9 is a diagram explaining an operation of the first modified example of the mounting device according to the embodiment of the present disclosure.

FIG. 10 is a schematic diagram of a second modified example of the mounting device according to the embodiment of the present disclosure.

FIG. 11 is a schematic diagram of a third modified example of the mounting device according to the embodiment of the present disclosure.

FIG. 12 is a diagram explaining a substrate on which a plurality of chip components are mounted with small gaps therebetween, mounting locations in which the chip components are mounted, and each of the substrate recognition marks.

FIG. 13 is a diagram explaining a problem when recognizing substrate recognition marks on the substrate on which a plurality of chip components are mounted with small gaps therebetween.

FIGS. 14A and 14B are diagrams showing examples of using substrate recognition marks in adjacent mounting areas at opposite corners when mounting a plurality of chip components with small gaps therebetween, with FIG. 14A showing an example where a chip component is not mounted in an adjacent mounting area, and FIG. 14B showing an example in which chip components are mounted in some of the adjacent mounting areas.

FIGS. 15A and 15B are diagrams showing examples of an improvement using substrate recognition marks in adjacent mounting areas when mounting a plurality of chip components with small gaps therebetween, with FIG. 15A showing an example where a chip component is not mounted in an adjacent mounting area, and FIG. 15B showing an example in which chip components are mounted in some of the adjacent mounting areas.

FIGS. 16A and 16B are diagrams explaining a mounting method in which a substrate position information acquisition step is performed in advance, using the mounting device according to the embodiment of the present disclosure.

FIG. 17 is a diagram explaining a substrate on which a plurality of chip components are mounted, mounting locations in which the chip components are mounted, and each of the substrate recognition marks.

FIG. 18 is a diagram showing a state in which chip recognition marks and substrate recognition marks face each other when mounting a chip component on a substrate.

FIG. 19 is a diagram showing an example of a configuration of a mounting device that performs mounting with chip recognition marks of a chip component and substrate recognition marks of a substrate facing each other.

FIG. 20 is a diagram showing a state in which alignment is performed with the chip recognition marks of the chip component and the substrate recognition marks of the substrate facing each other.

FIG. 21 is a diagram showing a state in which the chip recognition marks of the chip component and the substrate recognition marks of the substrate are facing in the same direction.

FIG. 22 is a diagram showing an example of a configuration of a mounting device that performs mounting in a state in which the chip recognition marks of the chip component and the substrate recognition marks of the substrate are facing in the same direction.

FIGS. 23A and 23B are diagrams showing a mounting device that performs mounting in a state in which the chip recognition marks of the chip component and the substrate recognition marks of the substrate are facing in the same direction, with FIG. 23A showing a state in which position information of a first substrate recognition mark and position information of a first chip recognition mark are being acquired, and FIG. 23B showing a state in which position information of the first substrate recognition mark and position information of the first chip recognition mark are being acquired.

### DETAILED DESCRIPTION OF EMBODIMENTS

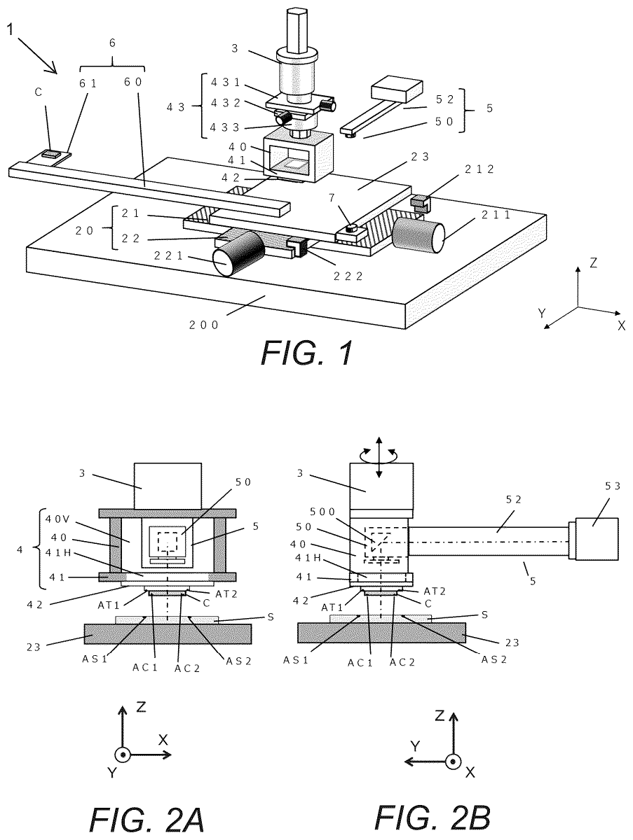

Selected embodiments of the present disclosure will be described below with reference to the drawings. FIG. 1 is a schematic diagram of a mounting device 1 according to an embodiment of the present disclosure.

A mounting device mounts chip components on a substrate, such as a wiring substrate, and the mounting device 1 of FIG. 1 is configured to perform face-down mounting, in which mounting is performed with the electrode surface of the chip component and the electrode surface of the substrate facing each other.

The constituent elements of the mounting device 1 include a substrate stage 2, an elevating means or unit 3, a mounting head 4, a substrate position recognition means or unit 5, a chip conveyance means or unit 6, and a chip position recognition means or unit 7.

In the mounting device 1 shown in FIG. 1, the substrate stage 2 is composed of a stage movement control means or unit 20 and a suction table 23. The suction table 23 uses suction to hold a substrate placed on the surface thereof, and the suction table 23 can be moved by the stage movement control means 20 in the in-plane direction of the substrate surface, while holding the substrate.

The stage movement control means 20 is composed of a Y direction stage movement control means 22 that is capable of moving the suction table 23 linearly in the Y direction, and an X direction stage movement control means 21 that is provided on a base 200 and is capable of moving the Y direction stage movement control means 22 linearly in the X direction. The Y direction movement control means 22 has a movable portion that is disposed on a slide rail and on which the suction table 23 is mounted, and the movement and position of the movable portion are controlled by a Y direction servo 221. The X direction movement control means 21 has a movable portion that is disposed on a slide rail and on which the Y direction movement control means 22 is mounted, and the movement and position of the movable portion are controlled by an X direction servo 211.

The elevating means 3 is fixed to a gate-shaped frame (not shown) and has a vertical drive shaft provided in a direction perpendicular to the suction table 23, and the mounting head 4 is linked to the vertical drive shaft. The elevating means 3 has a function of driving the mounting head 4 up and down, and of applying pressure according to a setting. In addition, with the mounting device 1, the elevating means 3 is supported from two directions (by a gate-shaped frame (not shown)), and is linked linearly to the mounting head 4, so lateral force is less likely to be applied to the mounting head 4 during pressure application. In the illustrated embodiment, the elevating means or unit 3 includes an electronic actuator or motor (i.e., an elevation actuator or motor) that drives the vertical drive shaft to drive the mounting head 4 up and down.

The mounting head 4 holds and pressure-bonds the chip component C parallel to the substrate (held by the suction table 23 of the substrate stage 2). The constituent elements of the mounting head 4 include a head body 40, a heater unit or heater 41, an attachment tool 42, and a tool position control means or unit 43. The head body 40 is linked to the elevating means 3 via the tool position control means 43, and the heater unit 41 is fixed and disposed on the lower side thereof. The heater unit 41 has a heat generating function, and heats the chip component C through the attachment tool 42. In addition, the heater unit 41 has a function of using suction to hold the attachment tool 42, using a reduced-pressure channel. The attachment tool 42 uses suction to hold the chip component C, and is replaced to match the shape of the chip component C. The tool position control means 43 finely adjusts the position of the head body 40 in the in-plane direction perpendicular to the vertical drive shaft of the elevating means 3, and the positions of the attachment tool 42 and the chip component C held by the attachment tool 42 (within the XY plane in the drawings) are adjusted accordingly. In the illustrated embodiment, the tool position control means 43 includes one or more electronic actuators or motors, for example.

The constituent elements of the tool position control means 43 include the electronic actuators that form an X direction tool position control means or unit 431, a Y direction tool position control means or unit 432, and a tool rotation control means or unit 433, respectively. In the embodiment shown in FIG. 1, the configuration is such that the tool rotation control means 433 adjusts the rotation direction of the head body 40, the Y direction tool position control means 432 adjusts the Y direction position of the tool rotation control means 433, and the X direction tool position control means 431 adjusts the X direction position of the Y direction position control means 432, but this is not the only option, so long as the X direction position, the Y direction position, and the rotation angle of the attachment tool 42 can be adjusted.

FIGS. 2A and 2B mainly show the periphery of the head body 40 (FIG. 2A is a front view, and FIG. 2B is a side view), but in the face-down mounting of the present embodiment, chip recognition marks AC (first chip recognition mark AC1 and second chip recognition mark AC2) are provided at diagonally opposite locations of the electrode surface of the chip component C, and substrate recognition marks AS (first substrate recognition mark AS1 and second substrate recognition mark AS2) are provided at guide positions at diagonally opposite mounting locations of the chip component on the electrode surface of the substrate S, with all of the marks facing the electrode surface of the substrate S of the mounting head 4.

In the present disclosure, tool recognition marks AT are provided on a surface of the attachment tool 42 that holds the chip component C, and a first tool recognition mark AT1 and a second tool recognition mark AT2 are arranged so as to correspond to the positions of the first chip recognition mark AC1 and the second chip recognition mark AC2 of the chip component C to be held.

The mounting device 1 is configured so that it is possible to observe the substrate recognition marks AS and the tool recognition marks AT through the mounting head 4, and either the attachment tool 42 is formed from a transparent member or a through-hole is provided that is aligned with the positions of the substrate recognition marks AS. In addition, the heater unit 41 either must be made of a transparent member or have an opening so that the tool recognition marks AT can be observed, and in this embodiment, a through-hole 41H is provided, as shown in FIGS. 2A and 2B. In addition, since a space into which an image capture unit 50 of the substrate position recognition means 5 can enter is required in order to observe the substrate recognition marks AS and/or the tool recognition marks AT, the mounting head 4 is provided with a head space 40V as shown in FIGS. 2A and 2B in this embodiment. That is, the head body 40 has a structure composed of side plates linked on the heater unit 41 and a top plate linking the two side plates.

The substrate position recognition means 5 acquires position information about the substrate recognition marks AS and/or the tool recognition marks AT, which are captured by focusing through the mounting head 4 (through the attachment tool 42 and the heater unit 41). In the present embodiment, the constituent elements of the substrate position recognition means or unit 5 include the image capture unit 50, an optical path 52, and an imaging means or unit 53 linked to the optical path 52. Thus, in the illustrated embodiment, the substrate position recognition means 5 includes a recognition mechanism. In the illustrated embodiment, the imaging means 53 includes an electronic image sensor, such as a charge-coupled device (CCD), an active-pixel sensor (CMOS sensor), and the like, for example.

The image capture unit 50 is disposed at the upper part of the recognition target from which the imaging means 53 acquires an image, and keeps the recognition target within the field of view. In the illustrated embodiment, the image capture unit 50 forms an objective, and includes an optical element, such as a lens or mirror, or combinations of several optical elements, for example. In the illustrated embodiment, the image capture unit 50 includes a reflecting means or unit 500 formed by a mirror or prism, for example.

Additionally, the substrate position recognition means 5 is configured to be capable of being moved, by a drive mechanism (not shown), in the in-plane direction of the substrate S (and the chip component C) within the head space 40V. Furthermore, the recognition mechanism is preferably able to move in a direction perpendicular to the substrate S (Z direction) so that the focal position can be adjusted.

The mounting head 4 is moved perpendicular to the substrate S by the elevating means 3, and this operation can be performed independently of the operation of the substrate position recognition means 5. Therefore, the head space 40V must be designed in a size such that the substrate position recognition means 5 entering the head space 40V will not interfere even if the mounting head 4 moves in the vertical direction.

The movable range of the image capture unit 50 of the substrate position recognition means 5 is not limited to the head space 40V; it is also possible to move on the substrate S outside of the head space 40V to acquire position information of the substrate recognition marks AS.

The chip conveyance means or unit 6 includes a conveyer that is formed by a conveyance rail 60 and a chip slider 61, and is configured so that the chip slider 61 holds and slides the chip component C supplied from a chip supply unit (not shown) to directly below the attachment tool 42.

Here, the chip supply unit (not shown) places the chip component C at a set position on the chip slider 61. If necessary, the position where the chip component C is placed on the chip slider 61 may be recognized by a recognition mechanism (not shown). In addition, the chip conveyance means 6 may include a position adjustment means or unit that adjusts the in-plane-direction (XY direction) position of the chip component C placed on the chip slider 61. In this case, the position adjustment means includes an adjuster or an electronic actuator that adjust the in-plane-direction position of the chip component C. Thus, controlling the positions of the chip slider 61 and the chip component C placed on the chip slider 61 allows the chip component C to be transferred within a prescribed range of the attachment tool 42. After the attachment tool 42 has held the chip component C, the chip slider 61, which has released the chip component C, moves to a retracted position.

The chip position recognition means 7 images the tool recognition marks AT and also images the chip recognition marks AC of the chip component C held by the attachment tool 42, to acquire position information of the chip recognition marks AC and the tool recognition marks AT. In the illustrated embodiment, the chip position recognition means 7 includes an electronic image sensor, such as a charge-coupled device (CCD), an active-pixel sensor (CMOS sensor), and the like, for example.

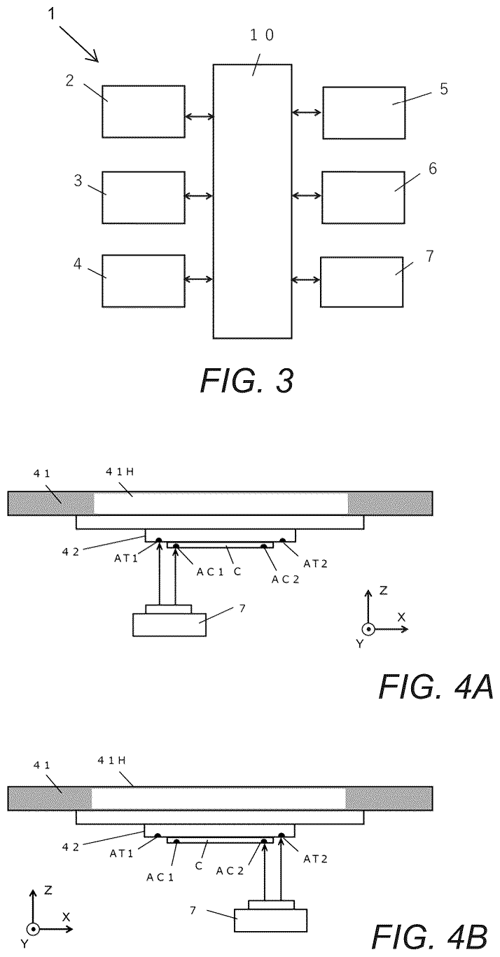

As shown in the block diagram of FIG. 3, the mounting device 1 comprises a control unit or electronic controller 10 that is connected to the substrate stage 2, the elevating means 3, the mounting head 4, the substrate position recognition means 5, the conveyance means 6, and the chip position recognition means 7.

Essentially, the main constituent elements of the control unit 10 include at least one processor having a CPU (Central Processing Unit) and a storage device or computer memory, and an interface for each device is included as necessary. In addition, the control unit 10 can have a built-in program to perform calculations using acquired data and to output according to the calculation result. Furthermore, it is preferable for the control unit 10 to have the function of recording and using the acquired data and the calculation result as data for new calculations.

The control unit 10 is connected to the substrate stage 2 and controls the operations of the X direction stage movement control means 21 and the Y direction stage movement control means 22, and thereby controls the in-plane movement of the suction table 23. In addition, the control unit 10 controls the suction table 23 to control the application and release of suction to and from the substrate S.

The control unit 10 is connected to the elevating means 3, controls the position of the mounting head 4 in the up and down direction (Z direction), and has the function of controlling the pressure applied when the chip component C is pressure-bonded to the substrate S.

The control unit 10 is connected to the mounting head 4, and has the function of controlling the application and release of suction to and from the chip component C by the attachment tool 42, the heating temperature of the heater unit 41, and the position within the XY plane of the head body 40 (and the heater unit 41 and the attachment tool 42) using the tool position control means 43.

The control unit 10 is connected to the substrate position recognition means 5, controls drive in the horizontal (in the XY plane) direction and the vertical direction (Z direction), and has a function of controlling the imaging means 53 to acquire image data. Furthermore, the control unit 10 has an image processing function, and has a function of calculating the positions of the substrate recognition marks AS and/or the tool recognition marks AT from an image acquired by the imaging means 53.

The control unit 10 is connected to the chip conveyance means 6, and has a function of controlling the position of the chip slider 61 that moves along the conveyance rail 60.

The control unit 10 is connected to the chip position recognition means 7, controls drive in the horizontal (in the XY plane) direction of the chip position recognition means 7, and has a function of controlling an imaging means (not shown) to acquire image data. Furthermore, the image processing function of the control unit 10 has a function of calculating the positions of the chip recognition marks AC and/or the tool recognition marks AT.

The steps by which the mounting device 1 aligns and mounts a chip component at a mounting location SC of the substrate S will be described below, with reference to FIGS. 4A to 7B; prior to this, the substrate S undergoes a substrate holding step and is held by the substrate stage 2 of the mounting device 1. Here, it is preferable that information on the placement of the substrate S with respect to the suction table 23 of the substrate stage 2 has been acquired by an image recognition means, or the like, and stored in the control unit 10.

In addition, the chip component C has been conveyed by the chip conveyance means 6 and has undergone a chip holding step in which the chip component C is held by the attachment tool 42. Here, a prescribed level of positional accuracy is ensured when the chip component C is handed over from a chip supply unit (not shown) to the chip slider 61, and then handed over from the chip slider 61 to the attachment tool 42, and the chip component C is held by the attachment tool 42 with a prescribed level of positional accuracy.

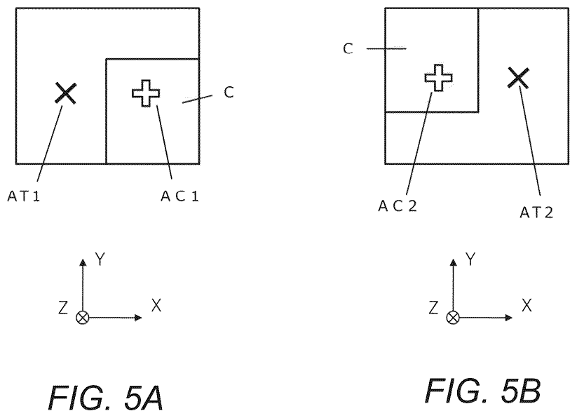

As a result, the chip position recognition means 7 can observe the chip recognition marks AC and the tool recognition marks AT within the same field of view at high magnification in the chip position information acquisition step shown in FIGS. 4A and 4B. That is, it is possible, in the state shown in FIG. 4A, to image the first chip recognition mark AC1 and the first tool recognition mark AT1 within the same field of view, as shown in FIG. 5A, and to obtain information on the relative positions of the first chip recognition mark AC1 and the first tool recognition mark AT1. Similarly, it is possible, in the state shown in FIG. 4B, to obtain an image as shown in FIG. 5B, and to obtain information on the relative positions of the second chip recognition mark AC2 and the second tool recognition mark AT2. From the position information of the chip recognition marks AC and of the tool recognition marks AT acquired from these two locations, it is possible to calculate position information of the first chip recognition mark AC1 and of the second chip recognition mark AC2 of the chip component C being held, with the position information of the first tool recognition mark AT1 and of the second tool recognition mark AT2.

In the mounting device 1 of FIG. 1, the chip position recognition means 7 is fixed to the suction table 23. Therefore, the stage movement control means 20 moves the suction table 23 such that the chip position recognition means 7 is disposed below the attachment tool 42.

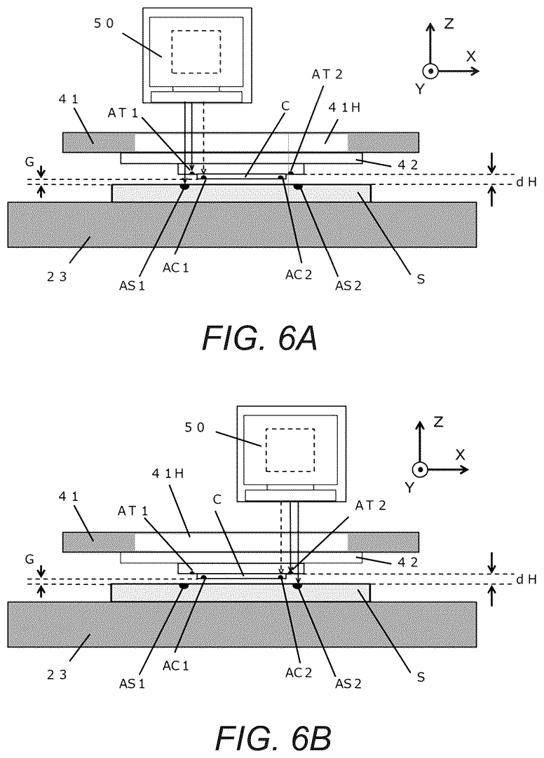

Subsequent to the chip position information acquisition step, the stage movement control means 20 moves the suction table 23 such that the chip mounting location SC is disposed directly below the attachment tool 42. Subsequently, the elevating means 3 is driven to lower the mounting head 4, and the chip component C is brought as close as possible to the substrate S without coming into contact (FIGS. 6A and 6B).

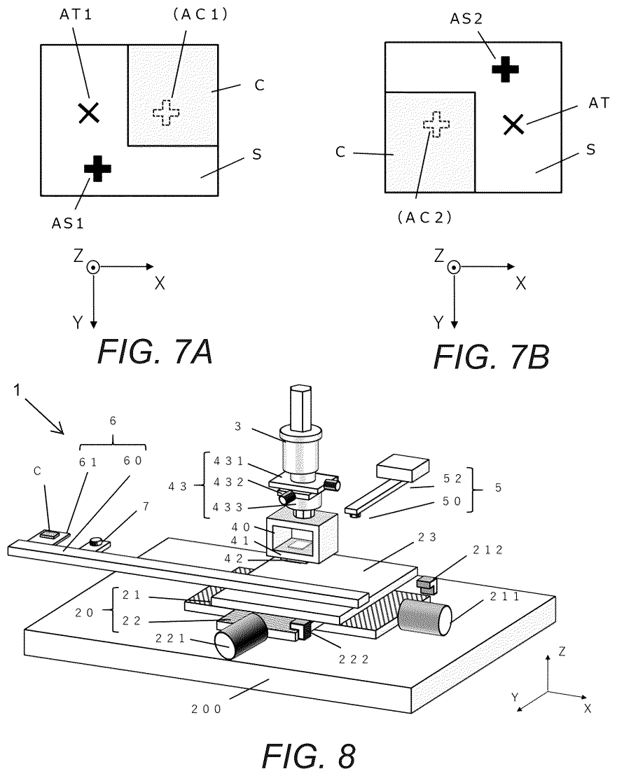

From this state, the substrate position recognition means 5 observes the substrate recognition marks AS from above the attachment tool 42 in the substrate position information acquisition step shown in FIGS. 6A and 6B, but the tool recognition marks AT can also be observed because the attachment tool 42 is transparent. Furthermore, as described above, because information on the placement of the substrate S on the suction table 23 has been obtained, the mounting location SC of the substrate S is disposed directly below the attachment tool 42, and the substrate position recognition means 5 is able to observe the substrate recognition marks AS and the tool recognition marks AT within the same field of view at high magnification. That is, it is possible, in the state shown in FIG. 6A, to image the first tool recognition mark AT1 and the first substrate recognition mark AS1 within the same field of view, as shown in FIG. 7A. Similarly, it is possible, in the state shown in FIG. 6B, to image the second tool recognition mark AT2 and the second substrate recognition mark AS2 within the same field of view, as shown in FIG. 7B.

The first chip recognition mark AC1 is shown in FIG. 7A and the second chip recognition mark AC2 is shown in FIG. 7B, but neither can be observed if the substrate position recognition means 5 is an imaging means for the visible light range. However, it is possible to obtain position information of the first chip recognition mark AC1 within the field of view shown in FIG. 7A and of the second chip recognition mark AC2 within the field of view shown in FIG. 7B, from the relative positional relationship between the chip recognition marks AC and the tool recognition marks AT obtained in the chip position information acquisition step.

Therefore, the positional relationship between the first chip recognition mark AC1 and the first substrate recognition mark AS1 and the positional relationship between the second chip recognition mark AC2 and the second substrate recognition mark AS2 can be determined, and, in the alignment step, the control unit 10 controls the tool position control means 43 and/or the stage movement control means 20 to perform alignment so as to correct the positional misalignment of the chip component C with respect to the mounting location SC of the substrate S.

Subsequently, the elevating means 3 is driven to lower the mounting head 4 and bring the chip component C into close contact with the substrate S, a prescribed amount of pressure is applied to the chip component C, and the heater unit 41 is heated to bond the electrodes of the substrate S and the chip component C. Since the distance of descent from the alignment step to the mounting step is very small, it is possible to perform mounting in which the accuracy of the alignment of the alignment step is maintained.

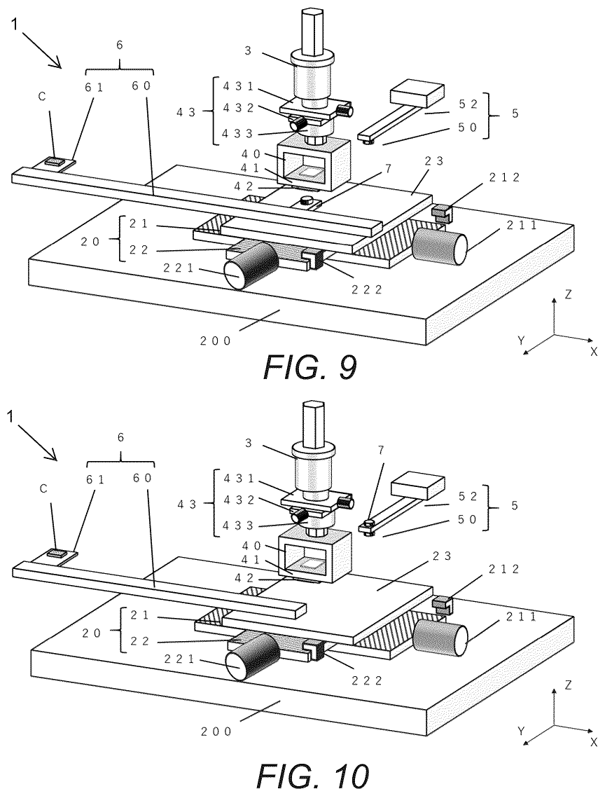

In the mounting device 1 shown in FIG. 1, the chip position recognition means 7 is configured to be provided on the suction table 23, but the arrangement location of the chip position recognition means 7 is not limited thereto. For example, in a first modified example shown in FIG. 8, the chip position recognition means 7 is provided so as to be slidable along the conveyance rail 60 of the chip conveyance means 6, and can be disposed below the attachment tool 42, as shown in FIG. 9. Furthermore, it is also possible to adopt a configuration in which the chip position recognition means 7 is combined with the substrate position recognition means 5, as in the second modified example shown in FIG. 10. In this configuration, by providing the substrate position recognition means 5 on a drive means that also moves in the up and down direction, it becomes possible for the chip position recognition means 7 to observe the chip component C that is held by the attachment tool 42.

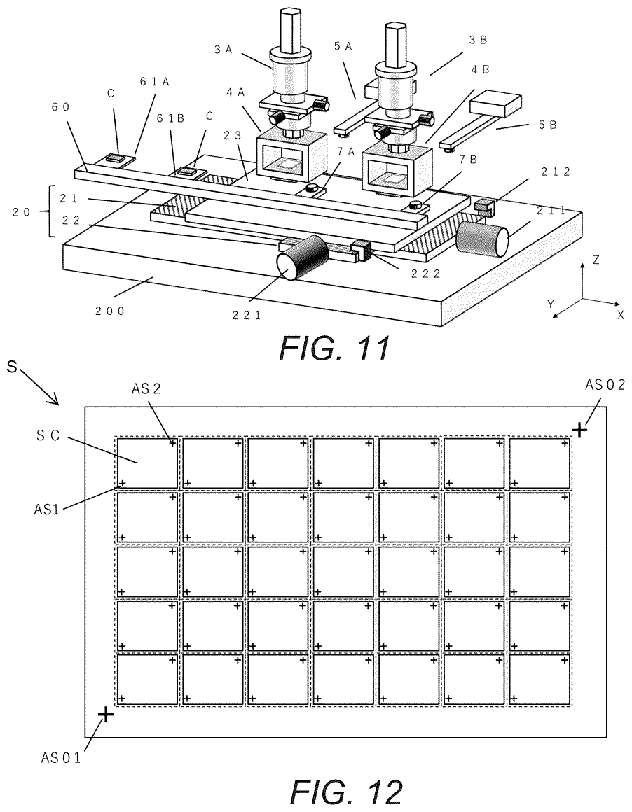

The third modified example of FIG. 11 shows an example in which a plurality of mounting heads 4 (4A and 4B) are provided for one substrate stage 23.

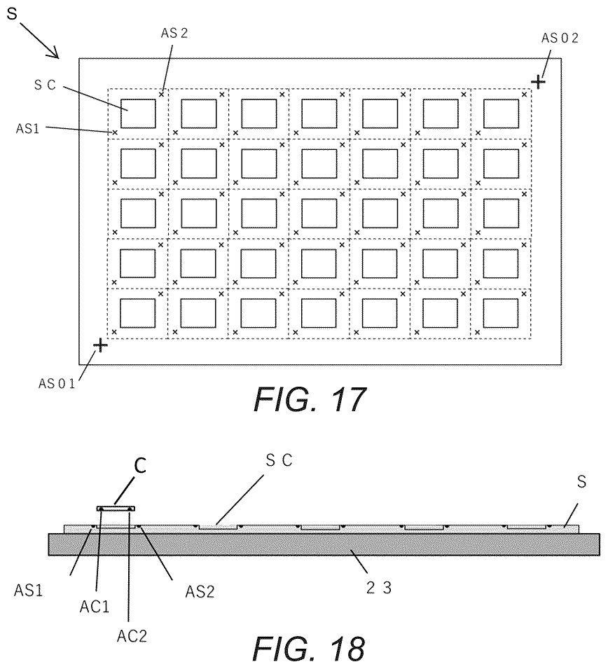

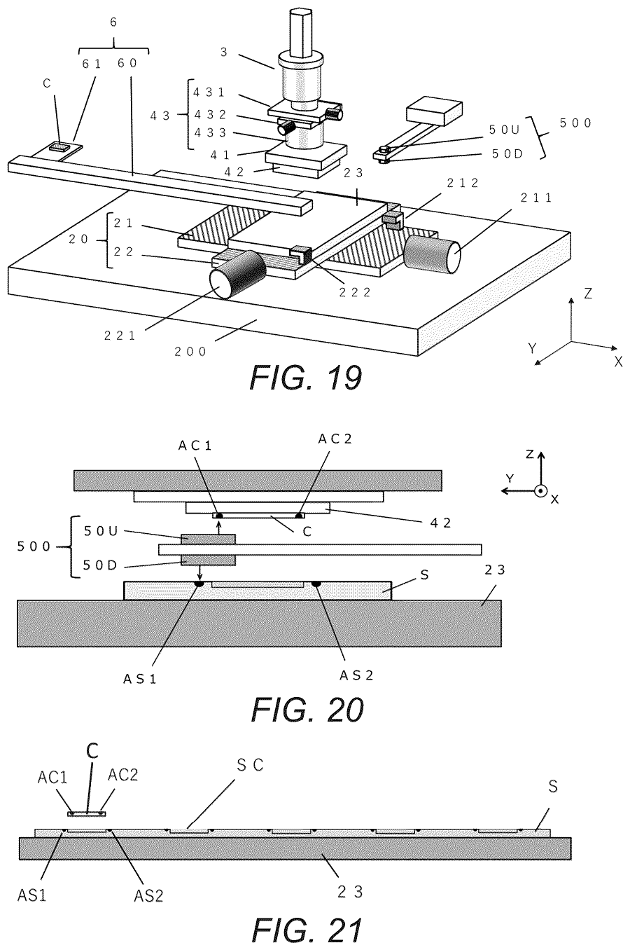

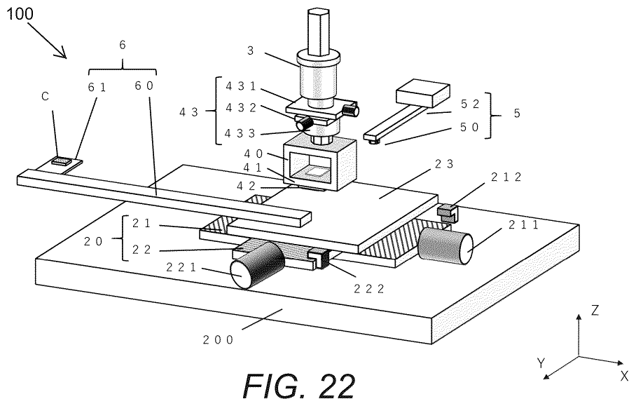

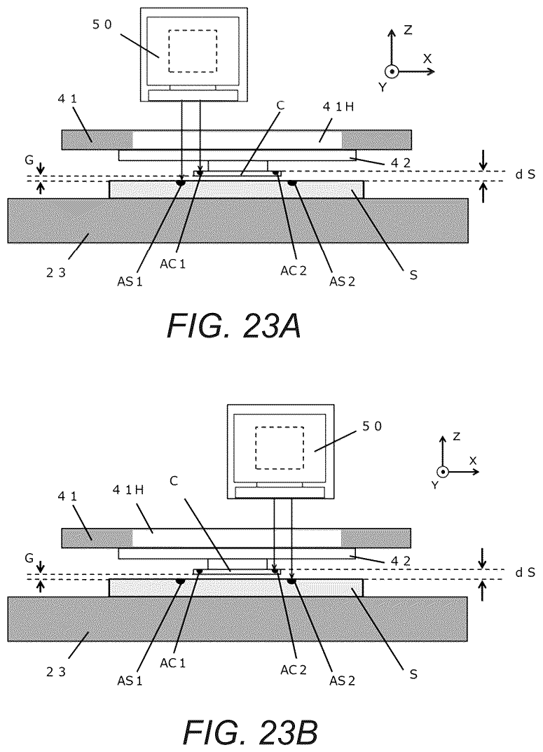

Recently, configurations in which mounting locations SC are arranged on the substrate S with small gaps therebetween have appeared, as shown in FIG. 12. In such a configuration, unlike modalities in which the substrate recognition marks AS are on the outer sides of the mounting locations SC, as shown in FIG. 17, the substrate recognition marks AS are provided within the mounting locations SC, as shown in FIG. 12.

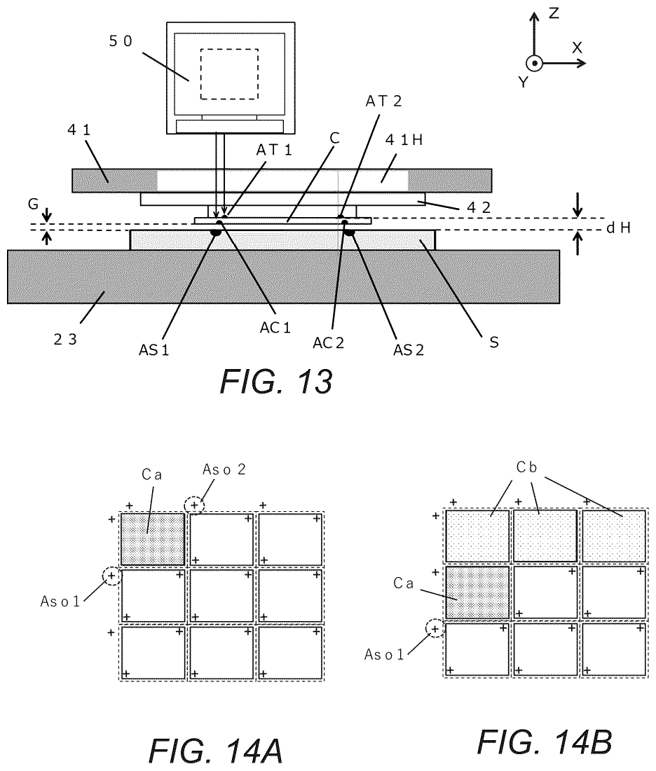

Therefore, even if the present disclosure is used in a configuration in which the mounting locations SC are arranged on the substrate S with small gaps therebetween, the substrate recognition marks AS are hidden behind the chip component and cannot be observed in the substrate position information acquisition step, as shown in FIG. 13.

Thus, FIGS. 14A and 14B show examples in which substrate recognition marks AS of adjacent mounting locations are used. That is, in mounting areas located diagonally opposite each other in FIG. 14A, it is possible to observe the first substrate recognition mark AS1 of the mounting area at the top right of the figure as a second substrate recognition mark Aso2 and to observe the second substrate recognition mark AS2 of the mounting area at the lower left of the figure as a first substrate recognition mark Aso1 on the outer side of a chip component Ca (to be aligned). However, if chip components Cb are disposed in the mounting locations, the substrate recognition marks AS on one of the opposite corners of the chip component Ca become unobservable due to the chip components Cb, as shown in FIG. 14B. Therefore, it is difficult to use the present disclosure to sequentially align and mount the chip components C at the mounting locations SC of the substrate S, such as shown in FIG. 12.

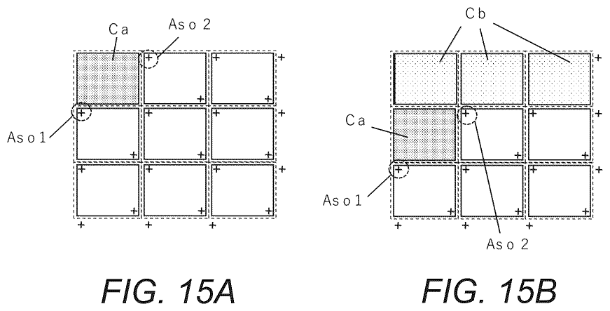

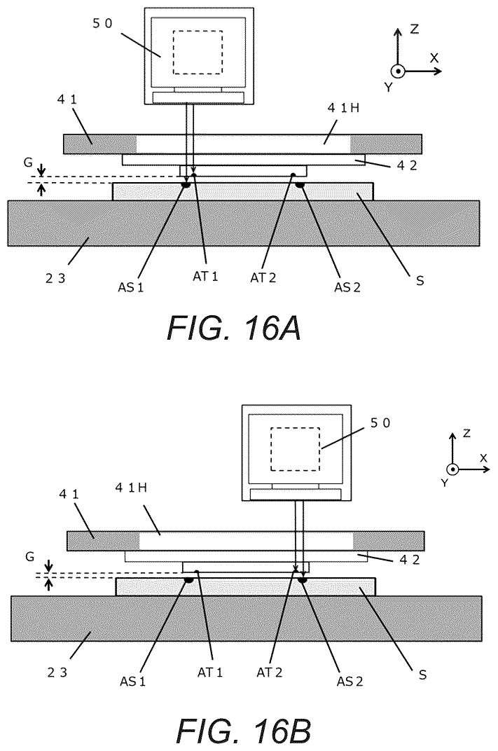

However, it is possible to handle this problem by exercising ingenuity in the arrangement of the substrate recognition marks AS provided in the mounting locations SC of the substrate S. That is, by providing a substrate recognition mark AS at the upper left of the figure for each mounting location SC, as shown in FIGS. 15A and 15B, it is possible to perform alignment using substrate recognition marks AS of the adjacent mounting locations to the right and below, although the marks are not exactly on a diagonal with respect to the chip recognition marks AC of the chip component Ca to be aligned. An example of the foregoing is shown in FIG. 15A; by repeating moving from this state to the right, and, after reaching the right end, moving to the left end of the row below, it is possible to use the present disclosure to align and mount chip components C at each mounting location of the substrate S.

In addition, by changing the order of the chip position information acquisition step and the substrate position information acquisition step, it is possible to perform alignment using substrate recognition marks AS within the mounting locations SC shown in FIG. 12, without using the substrate recognition marks AS in adjacent mounting areas.

That is, it makes use of the fact that, in a state in which a chip component C is not being held, as shown in FIGS. 16A and 16B, information on the relative positions of the tool recognition marks AT and the substrate recognition marks AS can be acquired by the substrate position recognition means 5 as the substrate position information acquisition step. Specifically, as shown in FIGS. 16A and 16B, the attachment tool 42 is brought close to the substrate S, the substrate position recognition means 5 is used to acquire the positional relationship (FIG. 16A) between the first tool recognition mark AT1 and the first substrate recognition mark AS1, and the positional relationship (FIG. 16B between the second tool recognition mark AT2 and the second substrate recognition mark AS2, and information on the relative position is stored.

Subsequently, the attachment tool 42 is raised and the chip component C is held (chip holding step), and the chip position recognition means 7 is used to acquire the positional relationship between the first chip recognition mark AC1 and the first tool recognition mark AT1, and the relative position information between the second chip recognition mark AC2 and the second tool recognition mark AT2 (chip position information acquisition step).

Using each piece of position information obtained in the procedure described above, the adjustment amount by which the tool position control means 43 should move the attachment tool 42 in order to align the chip component C with the mounting location SC of the substrate S is calculated, in a state in which the chip component C held by the attachment tool 42 is brought close to the substrate S, and the tool position control means 43 performs the positional adjustment (alignment step).

Subsequently, the elevating means 3 is driven to lower the mounting head 4 and bring the chip component C into close contact with the substrate S, a prescribed amount of pressure is applied to the chip component C, and the heater unit 40 is heated to bond the electrodes of the substrate S and the chip component C, as the mounting step (mounting step).

In the mounting step, the gap between the upper surface of the substrate S and the lower surface of the attachment tool 42 corresponds to the thickness of the chip component C. Therefore, in the substrate position information acquisition step shown in FIGS. 16A and 16B, if the gap G between the lower surface of the attachment tool 42 and the upper surface of the substrate S is made equal to the thickness of the chip component C, highly-accurate mounting becomes possible. For example, even if there is a slight tilt in the direction in which the elevating means 3 is driven, the gap G of the substrate position information acquisition step can be made equal to the thickness of the chip component C, thereby suppressing the positional misalignment of the mounting step. Even if an attempt is made to make the gap G between the lower surface of the attachment tool 42 and the upper surface of the substrate S in the substrate position information acquisition step to be exactly the same as the thickness of the chip component C, since there is variability in the thickness of the substrate S and the chip component C, it is sufficient if the gap is approximately equal to the thickness of the chip component C. Here, approximately equal to means that an error of ±30% relative to the designed thickness of the chip component C is allowed.

In the example described above, the attachment tool 42 holds the chip component C, after which the chip position recognition means 7 calculates the positional relationship between the chip recognition marks AC and the substrate recognition marks AS to perform the alignment step, but alignment may be performed at the stage when the attachment tool 42 holds the chip component C. Specifically, when the chip component C that is placed on the chip slider 61 of the chip conveyance means 6 is handed over to the attachment tool 42, the chip position recognition means 7 may acquire position information of the chip recognition marks AC and of the tool recognition marks AT and perform alignment (such that the chip recognition marks AC would have a prescribed positional relationship with respect to the substrate recognition marks AS), before the attachment tool 42 holds the chip component C. At this time, if the attachment tool 42 holds the chip component C without the tool position control means 43 being driven and positional adjustment is performed only on the chip slider 61 side, the chip component C can be mounted on the mounting location SC with high accuracy simply by lowering the mounting head 4 with the elevating means 3. That is, it is also possible to perform the alignment step prior to the chip holding step.

In the description above, position information of the tool recognition marks AT and the substrate recognition marks AS is acquired by the substrate position recognition means 5 in the substrate position information acquisition step, but alignment can be performed without acquiring position information of the tool recognition marks AT. That is, it is also possible to adjust the positions of the tool recognition marks AT such that the positions of the chip recognition marks AC match the position information of the substrate recognition marks AS, obtained by the substrate position recognition means 5 and stored by the control unit 10.

What is claimed is:

1. A mounting device configured to mount a chip component having a chip recognition mark for alignment and a substrate having a substrate recognition mark for alignment such that a surface having the chip recognition mark faces a surface having the substrate recognition mark, the mounting device comprising:
an attachment tool having transparency and having a tool recognition mark, the attachment tool being configured to hold a surface of the chip component opposite to the surface having the chip recognition mark;
a mounting head holding the attachment tool at a tip thereof;
an elevating unit configured to raise and lower the mounting head in a direction perpendicular to the substrate;
a substrate stage configured to hold the substrate;
a chip position recognition unit configured to simultaneously acquire position information of the chip recognition mark and position information of the tool recognition mark, in a state in which the chip component is held by the attachment tool;
a substrate position recognition unit configured to acquire position information of the substrate recognition mark and the position information of the tool recognition mark; and
a control unit connected to the mounting head, the elevating unit, the substrate stage, the chip position recognition unit, and the substrate position recognition unit,
at least one of the substrate stage and the attachment tool being movable in an in-plane direction of the substrate, and
the control unit being configured to move the substrate stage or the attachment tool in the in-plane direction of the substrate on the basis of information obtained by the chip position recognition unit and information obtained by the substrate position recognition unit to perform alignment between the chip component and the substrate.

2. The mounting device according to claim 1, wherein
the substrate position recognition unit is movable independent of the mounting head, and
the position information of at least one of the substrate recognition mark and of the tool recognition mark is acquired through the attachment tool.

3. The mounting device according to claim 1, wherein
the mounting head has a tool position control unit that is configured to adjust a position of the attachment tool in an in-plane direction of the chip component.

4. The mounting device according to claim 1, further comprising
a chip conveyance unit configured to convey the chip component to directly below the attachment tool, the chip conveyance unit including a chip slider on which the chip component is placed and a conveyance rail that is configured to convey the chip slider.

5. The mounting device according to claim 4, wherein
the chip conveyance unit includes a position adjustment unit that is configured to adjust an in-plane-direction position of the chip component placed on the chip slider.

6. The mounting device according to claim 1, wherein
the substrate position recognition unit is configured to simultaneously acquire the position information of the tool recognition mark and the position information of the substrate recognition mark, in a state in which the chip component is held by the attachment tool and is facing the substrate.

7. The mounting device according to claim 1, wherein
the substrate position recognition unit is configured to acquires the position information of the substrate recognition mark, in a state in which the chip component is not being held.

8. The mounting device according to claim 7, wherein
the attachment tool is brought close such that a distance between a lower surface of the attachment tool and an upper surface of the substrate becomes essentially equal to a thickness of the chip component, to simultaneously acquire the position information of the tool recognition mark and the position information of the substrate recognition mark.

9. A mounting method for mounting a chip component having a chip recognition mark for alignment and a substrate having a substrate recognition mark for alignment such that a surface having the chip recognition mark faces a surface having the substrate recognition mark, using the mounting device according to claim 1, the mounting method comprising:
holding the substrate on the substrate stage;
holding the chip component with the attachment tool having the tool recognition mark;
acquiring the position information of the chip recognition mark and the position information of the tool recognition mark, in a state in which the chip component is held by the attachment tool;
acquiring the position information of the tool recognition mark and the position information of the substrate recognition mark, in a state in which the chip component is held by the attachment tool and is facing the substrate; and
adjusting the position of the chip component in the in-plane direction of the substrate, on the basis of information on relative positions of the substrate recognition mark and the chip recognition mark with respect to the tool recognition mark.

10. A mounting method for mounting a chip component having a chip recognition mark for alignment and a substrate having a substrate recognition mark for alignment such that a surface having the chip recognition mark faces a surface having the substrate recognition mark, using the mounting device according to claim 1, the mounting method comprising:
holding the substrate on the substrate stage;
acquiring the position information of the substrate recognition mark;
holding the chip component with the attachment tool;
acquiring the position information of the chip recognition mark and the position information of the tool recognition mark, in a state in which the chip component is held by the attachment tool; and
adjusting the position of the chip component in the in-plane direction of the substrate, on the basis of information on relative positions of the tool recognition mark and the chip recognition mark.

11. The mounting method according to claim 10, wherein
in the acquiring of the position information of the substrate recognition mark, a distance between a lower surface of the attachment tool and an upper surface of the substrate is set to be essentially equal to a thickness of the chip component, to acquire the position information of the substrate recognition mark and the position information of the tool recognition mark.

12. The mounting device according to claim 2, wherein
the mounting head has a tool position control unit that is configured to adjust a position of the attachment tool in an in-plane direction of the chip component.

13. The mounting device according to claim 2, further comprising
a chip conveyance unit configured to convey the chip component to directly below the attachment tool, the chip conveyance unit including a chip slider on which the chip component is placed and a conveyance rail that is configured to convey the chip slider.

14. The mounting device according to claim 13, wherein
the chip conveyance unit includes a position adjustment unit that is configured to adjust an in-plane-direction position of the chip component placed on the chip slider.

15. The mounting device according to claim 3, further comprising
a chip conveyance unit configured to convey the chip component to directly below the attachment tool, the chip conveyance unit including a chip slider on which the chip component is placed and a conveyance rail that is configured to convey the chip slider.

16. The mounting device according to claim 15, wherein
the chip conveyance unit includes a position adjustment unit that is configured to adjust an in-plane-direction position of the chip component placed on the chip slider.

17. The mounting device according to claim 12, further comprising
a chip conveyance unit configured to convey the chip component to directly below the attachment tool, the chip conveyance unit including a chip slider on which the chip component is placed and a conveyance rail that is configured to convey the chip slider.

18. The mounting device according to claim 17, wherein
the chip conveyance unit includes a position adjustment unit that is configured to adjust an in-plane-direction position of the chip component placed on the chip slider.
